(19) United States
(12) Patent Application Publication
(10) Pub. No.: US 2025/0194317 A1
(43) Pub. Date: Jun. 12, 2025

(54) LIGHT-EMITTING DEVICE

(71) Applicant: NICHIA CORPORATION, Anan-shi (JP)

(72) Inventors: Takeshi KUSUSE, Tokushima-shi (JP); Mikiya ABE, Anan-shi (JP)

(73) Assignee: NICHIA CORPORATION, Anan-shi (JP)

(21) Appl. No.: 18/966,128

(22) Filed: Dec. 3, 2024

(30) Foreign Application Priority Data
Dec. 8, 2023 (JP) 2023-207678
Jul. 18, 2024 (JP) 2024-114421

(51) Int. Cl. H10H 20/858; H10H 20/853; H10H 20/857

(52) U.S. Cl. CPC H10H 20/8585; H10H 20/853; H10H 20/857; H10H 20/8582

(57) ABSTRACT

A light-emitting device including a first electrically-conductive member and a second electrically-conductive member, solder on upper surfaces of the first and second electrically-conductive members, a light-emitting element bonded to the upper surfaces of the first and second electrically-conductive members with the solder, a light-transmitting member on an upper surface of the light-emitting element, and a cover member covering the upper surfaces of the first and second electrically-conductive members and a lateral surface of the light-emitting element. A lateral surface of the first electrically-conductive member includes a first recessed surface contiguous with the upper surface and a second recessed surface located at a lower level than the first recessed surface. The solder continuously covers the upper surface of the first electrically-conductive member and at least part of the first recessed surface, and the cover member further covers the solder covering the first recessed surface and at least part of the second recessed surface.

### CROSS-REFERENCE TO RELATED APPLICATION

This application claims priority to Japanese Patent Application No. 2023-207678, filed on Dec. 8, 2023, and Japanese Patent Application No. 2024-114421, filed on Jul. 18, 2024, the disclosures of which are hereby incorporated by reference in their entireties.

### TECHNICAL FIELD

The present disclosure relates to light-emitting devices.

### BACKGROUND

Light-emitting devices are known in which a light-emitting element is placed on an electrically-conductive member (see, for example, Japanese Laid-Open Patent Publication No. 2003-086453).

Embodiments of the present disclosure provide light-emitting devices of excellent heat radiation.

### SUMMARY

A light-emitting device according to an embodiment includes: a first electrically-conductive member and a second electrically-conductive member each having an upper surface, a lower surface located opposite to the upper surface, and a lateral surface located between the upper surface and the lower surface; solder provided on the upper surface of the first electrically-conductive member and the upper surface of the second electrically-conductive member; a light-emitting element bonded to the upper surface of the first electrically-conductive member and the upper surface of the second electrically-conductive member with the solder; a light-transmitting member provided on an upper surface of the light-emitting element; and a cover member covering the upper surface of the first electrically-conductive member, the upper surface of the second electrically-conductive member, and a lateral surface of the light-emitting element. The lateral surface of the first electrically-conductive member includes a first recessed surface contiguous with the upper surface and a second recessed surface located at a lower level than the first recessed surface. The solder continuously covers the upper surface of the first electrically-conductive member and at least part of the first recessed surface, and the cover member further covers the solder covering the first recessed surface and at least part of the second recessed surface.

According to embodiments of the present disclosure, light-emitting devices of excellent heat radiation can be provided.

### BRIEF DESCRIPTION OF THE DRAWINGS

FIG. 1A is a schematic top view of a light-emitting device according to an embodiment of the present disclosure.

FIG. 1B is a schematic cross-sectional view taken along line IB-IB of FIG. 1A, with a partially-enlarged view thereof.

FIG. 1C is a schematic top view of a light-emitting device according to an embodiment of the present disclosure.

FIG. 1D is a schematic cross-sectional view taken along line ID-ID of FIG. 1C.

FIG. 2 is a schematic cross-sectional view of a light-emitting device according to an embodiment of the present disclosure, with a partially-enlarged view thereof.

FIG. 3 is a schematic cross-sectional view of a light-emitting device according to an embodiment of the present disclosure, with a partially-enlarged view thereof.

FIG. 4A is a schematic top view of a light-emitting device according to an embodiment of the present disclosure.

FIG. 4B is a schematic cross-sectional view taken along line IVB-IVB of FIG. 4A.

FIG. 4C is a schematic cross-sectional view taken along line IVC-IVC of FIG. 4A.

FIG. 4D is a schematic top view of a light-emitting

device according to an embodiment of the present disclosure.

FIG. 4E is a schematic top view of a light-emitting device according to an embodiment of the present disclosure.

FIG. 4F is a schematic top view of a light-emitting device according to an embodiment of the present disclosure.

FIG. 4G is a schematic top view of a light-emitting device according to an embodiment of the present disclosure.

FIG. 4H is a schematic cross-sectional view taken along line IVH-IVH of FIG. 4G.

FIG. 5A is a schematic top view of a light-emitting device according to an embodiment of the present disclosure.

FIG. 5B is a schematic cross-sectional view taken along line VB-VB of FIG. 5A.

FIG. 5C is a schematic cross-sectional view taken along line VC-VC of FIG. 5A.

FIG. 5D is a schematic cross-sectional view of a light-emitting device according to an embodiment of the present disclosure.

FIG. 6A is a schematic top view of a light-emitting device according to an embodiment of the present disclosure.

FIG. 6B is a schematic cross-sectional view taken along line VB-VB of FIG. 5A.

FIG. 6C is a schematic bottom view of a light-emitting device according to an embodiment of the present disclosure.

### DETAILED DESCRIPTION

Hereinafter, embodiments of the present disclosure are described in detail with reference to the drawings. In the following description, terms indicating specific directions and positions (e.g., “upper”, “lower”, “right”, “left”, and other terms including such terms) may be used when necessary. These terms are used merely for the ease of understanding the disclosure with reference to the drawings, but the meanings of the terms do not limit the technical range of the present disclosure. Herein, viewing in plan means viewing directly or in a see-through manner from the top or bottom surface. Parts of the same reference numerals which are shown in different drawings indicate identical parts or members.

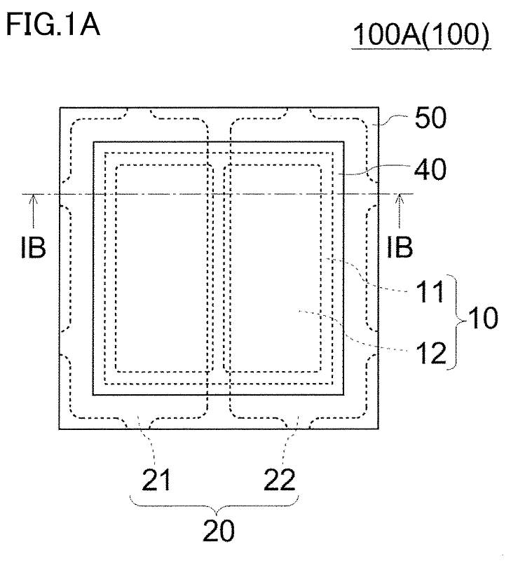

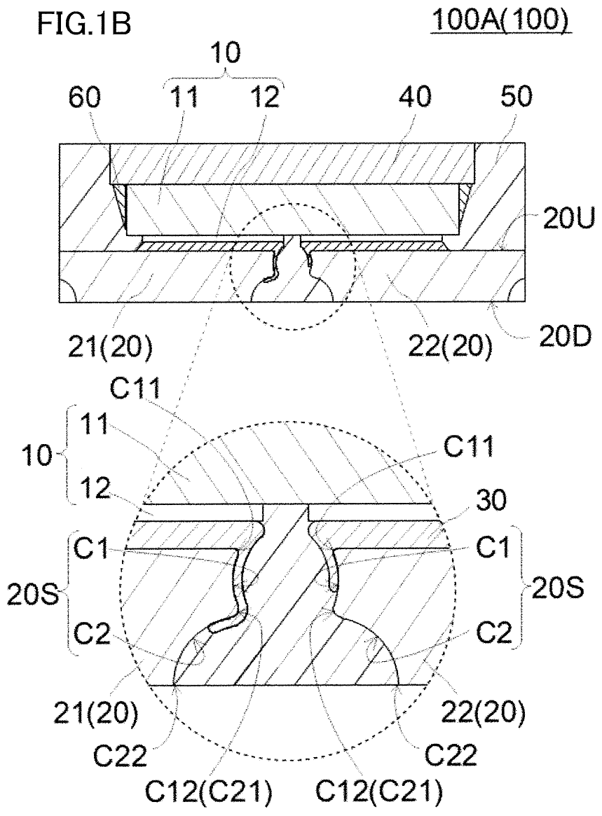

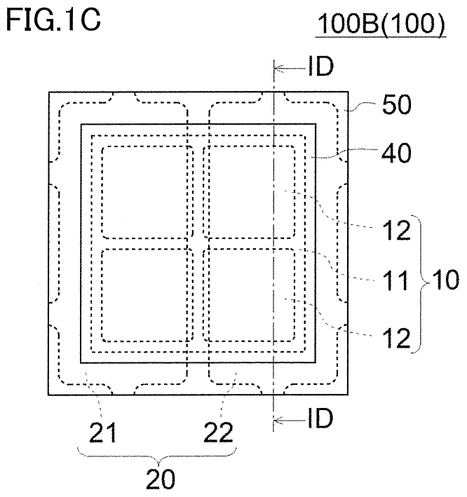

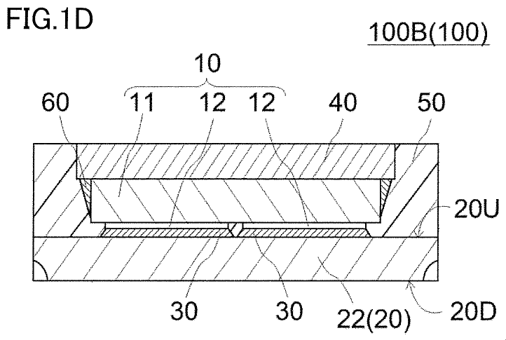

As shown in FIG. 1A and FIG. 1B, a light-emitting device 100 according to an embodiment includes an electrically-conductive member 20, at least one light-emitting element 10 provided on the electrically-conductive member 20 via solder 30, a light-transmitting member 40 provided on the light-emitting element 10, and a cover member 50 covering a lateral surface of the light-emitting element 10. Specifically, the electrically-conductive member 20 includes a first electrically-conductive member 21 and a second electrically-conductive member 22. The first electrically-conductive member 21 and the second electrically-conductive member 22 each have an upper surface 20U, a lower surface 20D located opposite to the upper surface 200, a lateral surface 20S located between the upper surface 20U and the lower surface 20D. The lateral surface 20S of the first electrically-conductive member 21 includes a first recessed surface C1 contiguous with the upper surface 200 and a second recessed surface C2 located at a lower level than the first recessed surface C1. The solder 30 is provided so as to continuously cover the upper surface 20U of the first electrically-conductive member 21 and at least part of the first recessed surface C1. The light-emitting element 10 is bonded to the upper surface 20U of the first electrically-conductive member 21 and the upper surface 20U of the second electrically-conductive member 22 via the solder 30. The light-transmitting member 40 is provided on the upper surface of the light-emitting element 10. The cover member 50 covers the upper surface 20U of the first electrically-conductive member 21, the upper surface 20U of the second electrically-conductive member 22, and the lateral surface of the light-emitting element 10. The cover member 50 further covers the solder 30 covering the first recessed surface C1 and at least part of the second recessed surface C2.

Since the solder 30 continuously covers the upper surface 20U of the first electrically-conductive member 21 and the first recessed surface C1, the contact area between the first electrically-conductive member 21 and the solder 30 increases. Accordingly, the heat from the light-emitting element 10 can be efficiently radiated, and the light-emitting device can achieve excellent heat radiation. The almost entire surface of the light-emitting element 10 as viewed in plan serves as a light-emitting region, and heat resulting from light emission is likely to accumulate particularly in a portion interposed between electrodes 12. A side where a pair of electrodes 12 face each other, i.e., a portion around the center of the light-emitting element 10, is required to achieve high heat radiation. Thus, by providing the solder 30 so as to extensively reside from the upper surface 20U to the lateral surface 20S of the electrically-conductive member 20, the heat can be efficiently spread from the side where the pair of electrodes 12 face each other to the electrically-conductive member 20.

Hereinafter, each of the components is described in detail.

### (Electrically-conductive Members)

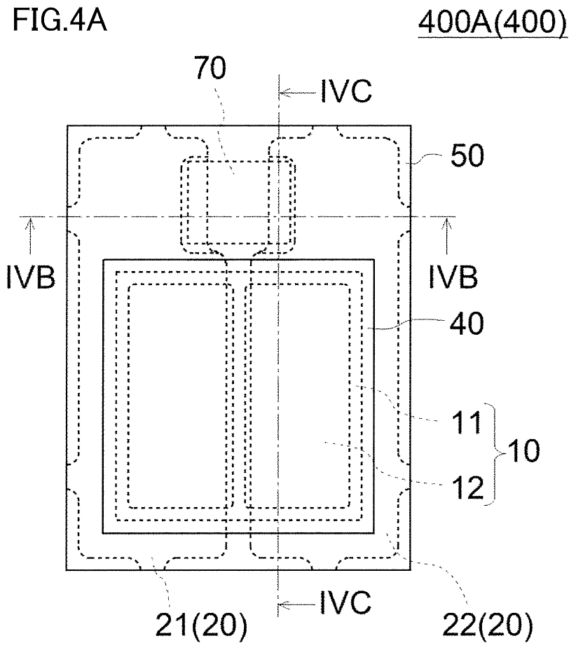

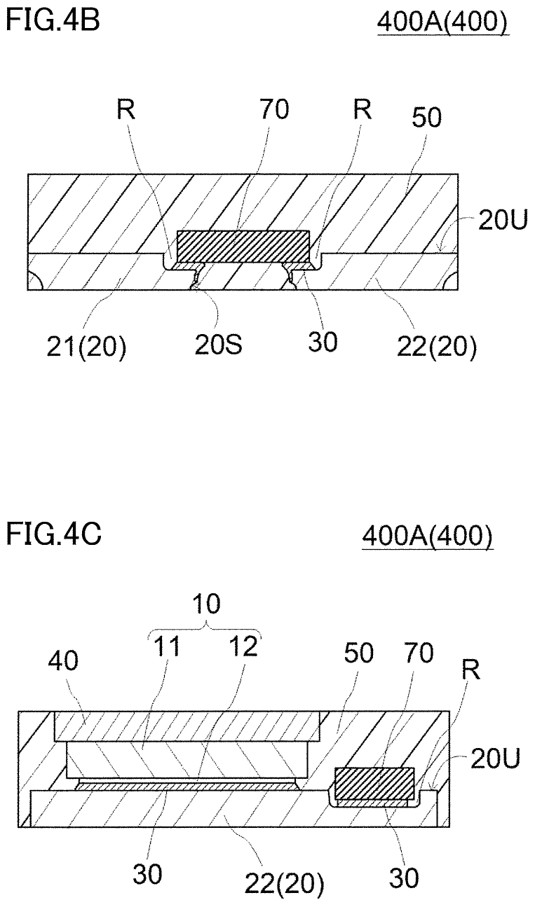

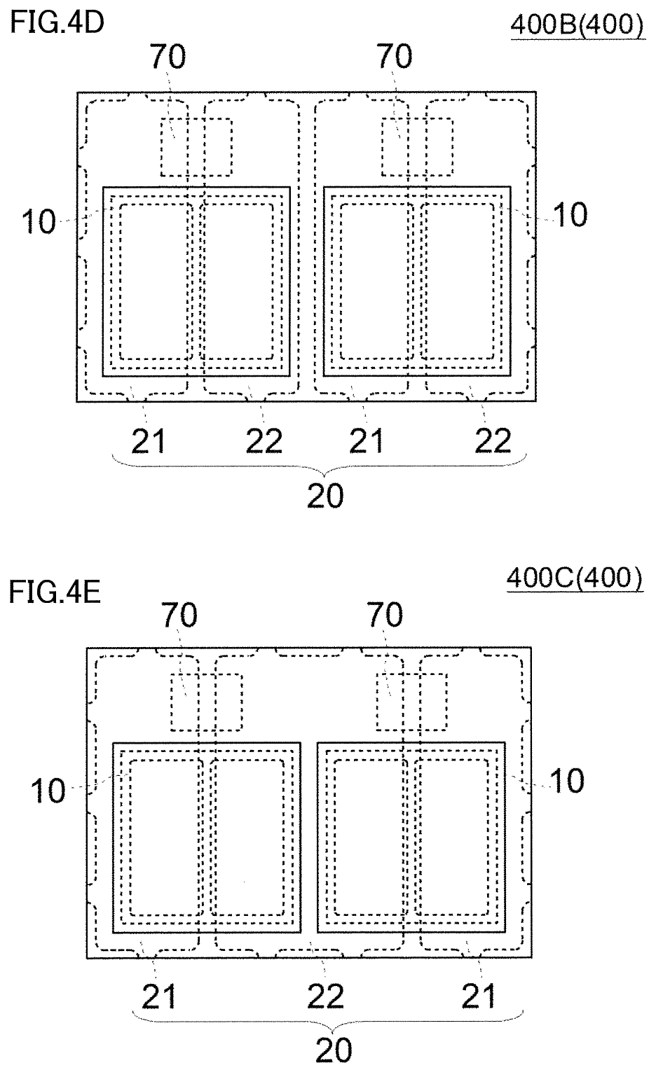

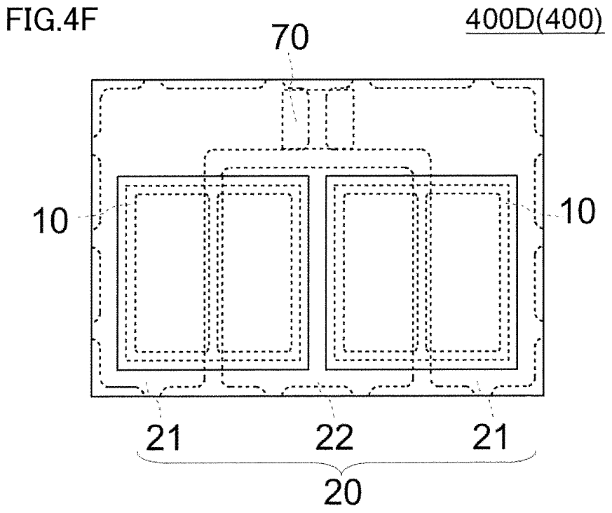

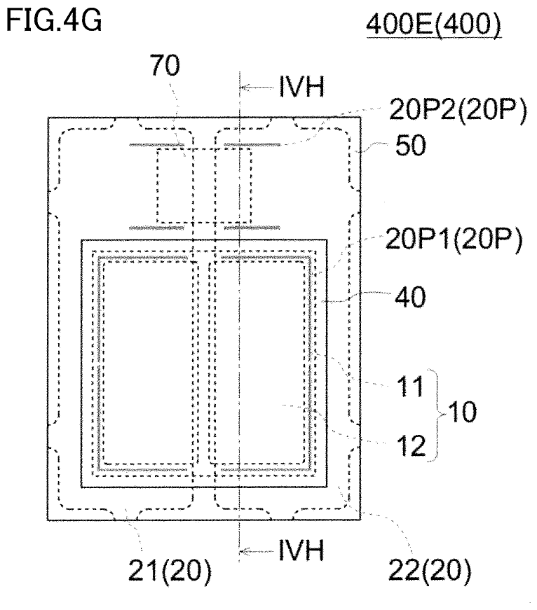

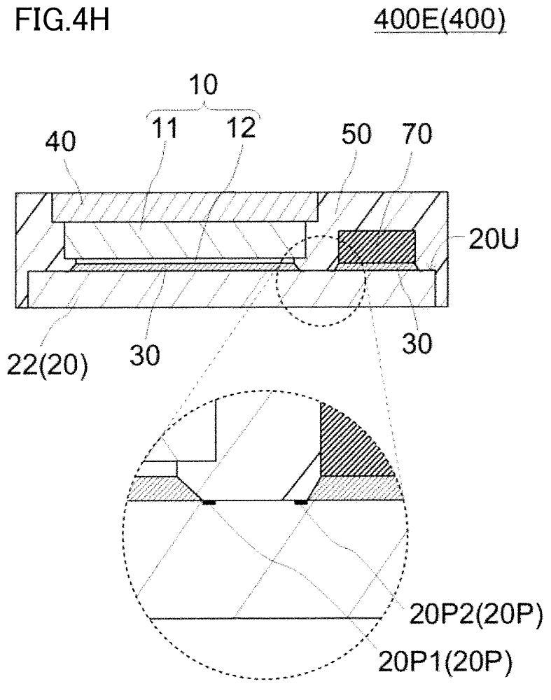

The electrically-conductive member 20 that includes the first electrically-conductive member 21 and the second electrically-conductive member 22 mainly functions as the electrode of the light-emitting device 100. When it is not necessary to distinguish the first electrically-conductive member 21 and the second electrically-conductive member 22 in the description, they are simply referred to as “electrically-conductive members” without “first” or “second”. The electrically-conductive member 20 can include, for example, three or more electrically-conductive members as shown in FIG. 4D, FIG. 4E and FIG. 4F. Further, the electrically-conductive member 20 can include an electrically-conductive member which does not contribute to conduction of electricity. The electrically-conductive member which does not contribute to conduction of electricity can function as, for example, a heat-radiation member.

The electrically-conductive member 20 is a plate-like metal member patterned into a predetermined shape and includes a base that is a main constituent and a plating layer formed on the surface of the base.

Examples of the material of the base include metals such as Cu, Al, Ag, Au, Zn, Cr, W, Co, Ni, Rh and Ru, and alloys of these metals. The base can be formed by a single layer or can have a multilayer structure (for example, cladding material). The base is preferably a metal plate containing Cu at 90% or higher as the major constituent. The base can contain non-metal elements such as Si and P as minute-quantity elements.

The thickness of the base is, for example, preferably about 100 μm to 800 μm, more preferably about 300 μm to 800 μm.

The plating layer provided on the surface of the base is preferably made of a material whose reflectance is higher than that of the base. Examples of the material of the plating layer include Ni, Ag, Au, Pt, Pd, Al, W, Mo, Ru and Rh. When the plating layer has a multilayer structure, it can be, for example, Ni/Pd/Au, Ni/Pt/Au, Ni/Au/Ag, or the like. Among others, Ni/Pd/Au is preferred.

The thickness of the plating layer is preferably about 1 μm to 10 μm, more preferably 1.5 μm to 6 μm.

The electrically-conductive member 20 has an upper surface 20U, a lower surface 20D located opposite to the upper surface 20U, and a lateral surface 20S located between the upper surface 20U and the lower surface 20D. The lateral surface 20S of the first electrically-conductive member 21 and the lateral surface 20S of the second electrically-conductive member 22 include, in the lateral surfaces 20S located so as to face each other, the first recessed surface C1 contiguous with the upper surface 20U and the second recessed surface C2 located at a lower level than the first recessed surface C1. In each of the first electrically-conductive member 21 and the second electrically-conductive member 22, a recessed surface that is contiguous with the upper surface 200 is referred to as “first recessed surface C1”, and a recessed surface located at a lower level than the first recessed surface C1 is referred to as “second recessed surface C2”. The first recessed surface C1 and the second recessed surface C2 can be located contiguous to each other. Alternatively, the first recessed surface C1 and the second recessed surface C2 can be separately located with a flat surface portion interposed therebetween. The lateral surface of the electrically-conductive member 20 is exposed to the outside at the lateral surface of the light-emitting device 100. The exposed lateral surface of the electrically-conductive member 20 which is contiguous with the upper surface 20U is not a curved surface but a flat surface. The upper surface 20U of the first electrically-conductive member 21 and the upper surface 20U of the second electrically-conductive member 22 are flat surfaces located on the same plane and are not exposed to the outside. As shown in FIG. 4G and FIG. 4H, the upper surface 200 of the first electrically-conductive member 21 and the upper surface 20U of the second electrically-conductive member 22 can each include processed portions 20P. The processed portions 20P have a concave, convex, or concave-convex shape as viewed in cross section. The height or depth of the processed portions 20P from a flat portion of the upper surface 200 of the electrically-conductive member 20 can be, for example, 1 μm to 10 μm. The width (the dimension in a direction perpendicular to the direction of extension) of the processed portions 20P can be, for example, 10 μm to 100 μm in a top view.

The processed portions 20P can be formed by, for example, irradiating the upper surface 20U, which is a flat surface, with laser light. Alternatively, the processed portions 20P can be formed by pressing with a mold, or the like, etching, blast, etc. For example, when a plating layer of a multilayer structure consisting of the outermost surface of Au and the underlayer of Ni is formed on the surface of the base of the electrically-conductive member 20 which contains Cu as the major constituent, it is preferred that Ni is exposed at the processed portions 20P. This arrangement can efficiently reduce flowage of the solder 30 into an unintended region.

In the example shown in FIG. 4G, the light-emitting element 10 and a protective element 70 are provided on the same plane. The processed portions 20P include processed portions 20P1 located around the light-emitting element 10 and processed portions 20P2 located around the protective element 70. Due to the presence of the processed portions 20P, flowage of the solder 30 into an unintended region can be reduced.

The processed portions 20P1 are located so as to extend along three sides of the outer periphery of the electrodes 12 of the light-emitting element 10 except for the side where the first electrically-conductive member 21 and the second electrically-conductive member 22 face each other. The processed portions 20P1 can be located such that portions extending along the short sides of the rectangular electrodes 12 and portions extending along the long sides of the rectangular electrodes 12 are contiguous with one another as shown in FIG. 4G. The portions extending along the long sides of the electrodes 12 can be continuous or can be partially separated as shown in FIG. 4G. Since the processed portions 20P are thus arranged so as to surround the outer periphery of a pair of electrically-conductive members 20, this arrangement can reduce movement of the light-emitting element 10 to an unintended position which can occur when the solder 30 melts. Thus, the light-emitting element 10 can be located with high positional accuracy.

The processed portions 20P2 extend in a direction parallel to the short sides of the electrodes 12 of the light-emitting element 10 and are located such that the protective element 70 is interposed between the processed portions 20P2. This arrangement can reduce movement of the protective element 70 toward the light-emitting element 10 side which can occur when the solder 30 melts. Particularly, as viewed from the top, if the processed portions 20P2 located between the light-emitting element 10 and the protective element 70 are placed at positions away from the outer periphery of the protective element 70, this arrangement can further reduce movement of the protective element 70 toward the light-emitting element 10 side which can occur when the solder 30 melts. The processed portions 20P2 can be located so as to surround the outer periphery of the protective element 70 as viewed from the top, similarly to the processed portions 20P1.

The lower surface 20D of the first electrically-conductive member 21 and the lower surface 20D of the second electrically-conductive member 22 are flat surfaces located on the same plane and are exposed to the outside. The light-emitting element 10 is provided on both the upper surface 20U of the first electrically-conductive member 21 and the upper surface 20U of the second electrically-conductive member 22 so as to extend from one to the other. That is, under the light-emitting element 10, the lateral surface 20S of the first electrically-conductive member 21 and the lateral surface 20S of the second electrically-conductive member 22 face each other. Among the lateral surfaces 20S of the electrically-conductive member 20, at least the lateral surface 20S of the first electrically-conductive member 21 which is one of the lateral surfaces 20S that face each other includes a first recessed surface C1 contiguous with the upper surface 20U and a second recessed surface C2 located at a lower level than the first recessed surface C1.

The distance between the electrodes 12 of the light-emitting element 10 can be smaller than the distance between an upper end C11 of the first recessed surface C1 of the first electrically-conductive member 21 and an upper end C11 of the first recessed surface C1 of the second electrically-conductive member 22. Since the solder 30 is in contact with the entire surfaces of the electrodes 12, even if the distance between the electrodes 12 is reduced, the heat produced in a portion interposed between the electrodes 12 can be sufficiently transferred to the electrically-conductive member via the solder 30, so that heat radiation can be improved.

The first recessed surface C1 and the second recessed surface C2 can be provided in only one of the first electrically-conductive member 21 and the second electrically-conductive member 22 or can be provided in both of them. Preferably, the first recessed surface C1 and the second recessed surface C2 are provided in both of the first electrically-conductive member 21 and the second electrically-conductive member 22. In the example described hereinafter, each of the first electrically-conductive member 21 and the second electrically-conductive member 22 includes the first recessed surface C1 and the second recessed surface C2.

The upper end C11 of the first recessed surface C1 is positioned at an end portion of the upper surface 20U of the electrically-conductive member 20. As shown in FIG. 1B, the upper surface 20U of the electrically-conductive member 20 can include a curved surface, or a flat surface, in a portion including the end portion as viewed in cross section. The lower end C12 of the first recessed surface C1 is positioned between the upper surface 20U and the lower surface 20D of the electrically-conductive member 20. The distance (the distance in the vertical direction) of the lower end C12 of the first recessed surface C1 from the upper surface 20U can be, for example, 10% to 90% of the distance from the upper surface 20U to the lower surface 20D (the thickness of the electrically-conductive member). The distance (the distance in the vertical direction) of the lower end C12 of the first recessed surface C1 of the first electrically-conductive member 21 from the upper surface 20U can be equal to, or different from, the distance (the distance in the vertical direction) of the lower end C12 of the first recessed surface C1 of the second electrically-conductive member 22 from the upper surface 20U.

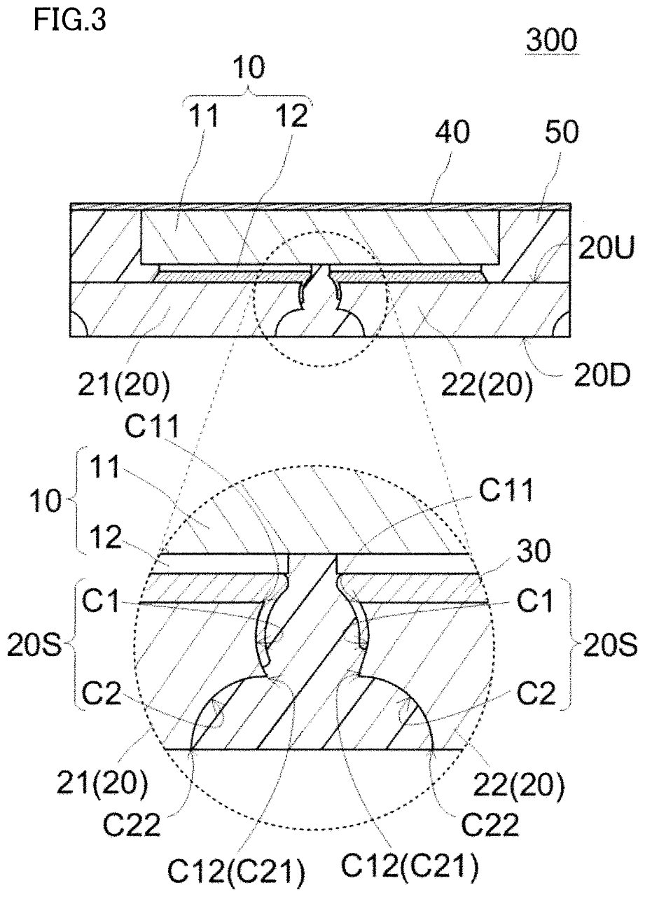

The lower end C12 of the first recessed surface C1 of the first electrically-conductive member 21 can be positioned on the second electrically-conductive member 22 side relative to the upper end C11 of the first recessed surface C1 as shown in, for example, FIG. 3. Alternatively, the upper end C11 of the first recessed surface C1 of the first electrically-conductive member 21 can be located on the second electrically-conductive member 22 side relative to the lower end C12 of the first recessed surface C1. Alternatively, the upper end C11 and the lower end C12 of the first recessed surface C1 of the first electrically-conductive member 21 and/or the second electrically-conductive member 22 can be coincident with each other as viewed in plan as shown in, for example, FIG. 1B.

The upper end C21 of the second recessed surface C2 of the first electrically-conductive member 21 can be coincident with the lower end C12 of the first recessed surface C1 or can be separated from the lower end C12 of the first recessed surface C1 with a flat surface portion, or the like, interposed therebetween. In the example shown in FIG. 1B, the lower end C12 of the first recessed surface C1 and the upper end C21 of the second recessed surface C2 are coincident with each other and positioned at the tip of a curved surface portion as viewed in cross section. In the example shown in FIG. 3, the lower end C12 of the first recessed surface C1 and the upper end C21 of the second recessed surface C2 are coincident with each other and positioned at the tip of a pointy shape portion as viewed in cross section.

When there is a flat surface portion between the first recessed surface C1 and the second recessed surface C2, the angle defined by the flat surface portion and the upper surface 20U of the first electrically-conductive member 21 can be perpendicular or slanted. Either one or both of the first electrically-conductive member 21 and the second electrically-conductive member 22 can include the flat surface portion. When there is the flat surface portion, the distance in the vertical direction of the upper end C21 of the second recessed surface C2 from the upper surface 20U of the electrically-conductive member 20 can be, for example, 10% to 90% of the distance from the upper surface 20U to the lower surface 20D (the thickness of the electrically-conductive member).

The lower end C22 of the second recessed surface C2 of the first electrically-conductive member 21 can be positioned on the second electrically-conductive member 22 side relative to the upper end C21 of the second recessed surface C2. Alternatively, the upper end C21 of the second recessed surface C2 of the first electrically-conductive member 21 can be positioned on the second electrically-conductive member 22 side relative to the lower end C22 of the second recessed surface C2 as shown in FIG. 1B. Alternatively, the upper end C21 and the lower end C22 of the second recessed surface 2 of the first electrically-conductive member 21 and/or the second electrically-conductive member 22 can be coincident with each other as viewed in plan.

### (Solder)

The solder 30 is an electrically-conductive material that electrically connects a pair of positive and negative electrodes 12 of the light-emitting element 10 with the electrically-conductive member 20. One of the electrodes 12 of the light-emitting element 10 is electrically bonded with the first electrically-conductive member 21 via the solder 30, and the other electrode 12 of the light-emitting element 10 is electrically bonded with the second electrically-conductive member 22 via the solder 30. The solder 30 is preferably in contact with the entire lower surface of the electrodes 12 of the light-emitting element 10. The solder 30 can have a thickness of 5 μm to 20 μm between the light-emitting element 10 and the upper surface 20U of the electrically-conductive member 20.

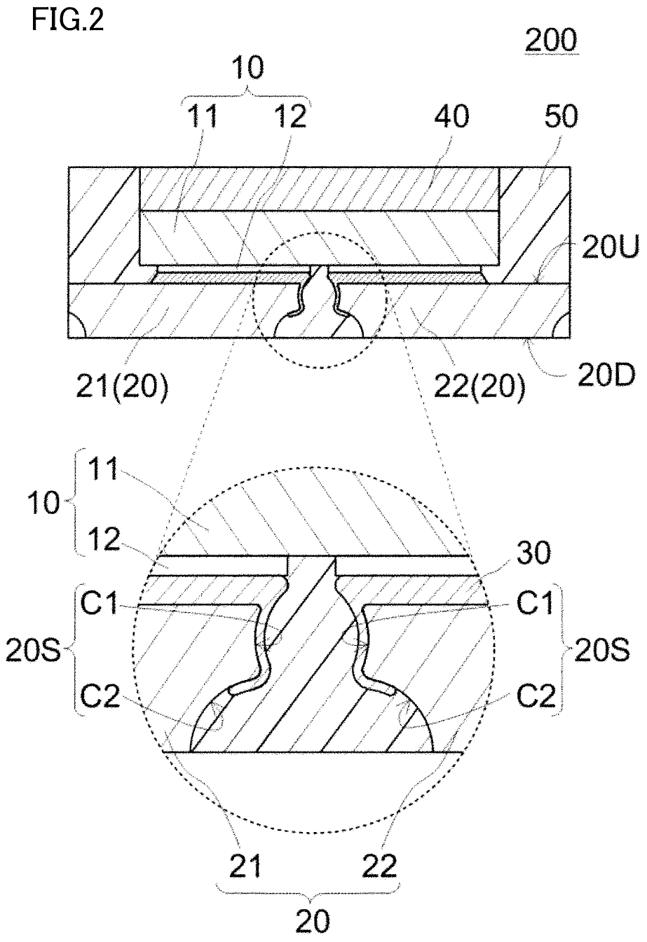

As shown in FIG. 3, the solder 30 continuously covers the upper surface 20U of the electrically-conductive member 20 and at least part of the first recessed surface C1 that is contiguous with the upper surface 20U. This arrangement can improve heat radiation as compared with a case where the solder 30 covers only the upper surface 20U. The solder 30 can further continuously cover part of the second recessed surface C2 of the electrically-conductive member 20 as shown in FIG. 1B or FIG. 2. This arrangement can further improve heat radiation. The thickness of the solder covering the upper surface 20U of the electrically-conductive member 20 is greater than the thickness of the solder 30 covering the first recessed surface C1. The thickness of the solder 30 covering the first recessed surface C1 can be, for example, 1 μm to 20 μm.

In both of the first electrically-conductive member 21 and the second electrically-conductive member 22, the solder 30 can cover only the upper surface 200 and at least part of the first recessed surface C1 as shown in FIG. 3 or can cover the upper surface 200, the first recessed surface C1 and at least part of the second recessed surface C2 as shown in FIG. 2. Alternatively, the solder 30 covers not only the upper surface 20U and at least part of the first recessed surface C1 of the second electrically-conductive member 22 but also the upper surface 200, the first recessed surface C1 and at least part of the second recessed surface C2 of the first electrically-conductive member 21 as shown in FIG. 1B. The solder 30 preferably covers the entirety of the first recessed surface C1 located below the light-emitting element 10. Also, the solder 30 preferably covers a region between the upper end C21 and the lower end C22 of the second recessed surface C2 located below the light-emitting element 10. The solder 30 preferably covers the region to the extent of 1 μm to 20 μm. The solder 30 preferably covers a portion away from the lower end C22 of the second recessed surface C2. In other words, it is preferred that the solder 30 does not reach the lower surface 20D of the electrically-conductive member 20.

The solder 30 is provided at such a position that the entirety of the solder 30 overlaps the light-emitting element 10 as viewed in plan. Note that, however, part of the solder 30 doesnot have to overlap the light-emitting element 10, i.e., can be outside the extent of the light-emitting element 10 as viewed in plan.

Examples of the material of the solder 30 include Au—Sn, Sn—Ag—Cu, Sn—Cu, Sn—Sb, Sn—Bi, Sn—In, Sn—Pb and Ni—Sn.

### (Light-emitting Element)

The light-emitting device includes one or more light-emitting elements 10. The light-emitting element 10 can be, for example, a semiconductor light-emitting element such as light-emitting diode. The light-emitting element 10 includes a semiconductor layered structure 11 and a pair of positive and negative electrodes 12. The semiconductor layered structure 11 includes, for example, an element substrate of sapphire, or the like, and semiconductor layers formed on the element substrate. Alternatively, the semiconductor layered structure 11 does not have to include the element substrate but can include only semiconductor layers. The shape of the light-emitting element 10 as viewed in plan can be a polygonal shape, such as a triangular, quadrangular, or hexagonal shape. The size of the light-emitting element 10 can be such that, for example, the length of one side is equal to or greater than 100 μm and equal to or smaller than 3000 μm as viewed in plan. Specifically, the light-emitting element 10 can have the shape of a square of about 600 μm, about 1000 μm, about 1400 μm, or about 1700 μm on each side. Alternatively, the light-emitting element 10 can have a rectangular shape that has long sides and short sides as viewed in plan. For example, the size of the light-emitting element 10 can be 1100 μm×200 μm. When the light-emitting device includes a plurality of light-emitting elements 10, the light-emitting elements 10 can have equal sizes, equal emission wavelengths, and equal compositions, although some or all of these specifications can be different. All of the plurality of light-emitting elements 10 can be connected in series or in parallel, and serial connection and parallel connection can be employed together.

The semiconductor layered structure 11 includes a n-type semiconductor layer, a p-type semiconductor layer, and an emission layer interposed between these semiconductor layers. Such a semiconductor layered structure including the emission layer can include, for example, InₓAl_{y}Ga_{1-x-y}N (0≤x, 0≤y, x+y≤1).

The semiconductor layered structure 11 can have such a structure that includes one or more emission layers between the n-type semiconductor layer and the p-type semiconductor layer. Alternatively, the semiconductor layered structure 11 can have such a structure that a unit structure including a n-type semiconductor layer, an emission layer, and a p-type semiconductor layer in this order is repeated multiple times. When the semiconductor layered structure 11 includes a plurality of emission layers, the semiconductor layered structure 11 can include emission layers of different emission peak wavelengths or can include emission layers of equal emission peak wavelengths. Note that the term “equal emission peak wavelengths” includes a case where they have variations of about several nanometers (nm). The combination of emission peak wavelengths among the plurality of emission layers can be appropriately selected. For example, when the semiconductor layered structure includes two emission layers, the emission layers can be selected in the combination of blue light and blue light, green light and green light, red light and red light, ultraviolet light and ultraviolet light, blue light and green light, blue light and red light, green light and red light, or the like.

The light-emitting element includes at least one pair of electrodes on the lower surface side of the semiconductor layered structure. In other words, a single light-emitting element includes at least one positive electrode and at least one negative electrode as its electrodes. In the light-emitting device 100A shown in FIG. 1A, the light-emitting element 10 includes one positive electrode and one negative electrode. The positive electrode and the negative electrode each have a rectangular shape as viewed in plan. When the light-emitting element 10 includes one positive electrode and one negative electrode as described herein, the size of each electrode can be increased. Accordingly, the contact area with the solder 30 can be increased, so that heat radiation can be improved.

At the upper end C11 of the first recessed surface C1 of the electrically-conductive member 20, i.e., at a corner portion (edge) between the upper surface 20U and the lateral surface 20S, the stress due to the difference in thermal expansion coefficient between the light-emitting element 10 and the electrically-conductive member 20 is likely to occur. Therefore, a portion of the electrode 12 overlapping the edge of the electrically-conductive member 20 as viewed in plan can be separated. For example, the electrodes 12 shown in FIG. 1A each have a rectangular shape, and a portion of the electrode 12 extending from one end to the other end overlaps a portion of the edge of the electrically-conductive member 20. On the other hand, the electrode 12 can have a shape that is recessed inward from the long side of the electrode 12 as viewed in plan such that the electrode 12 is not located on the portion overlapping the edge of the electrically-conductive member 20.

Alternatively, as in the light-emitting device 100B shown in FIG. 1C, the light-emitting element can include two positive electrodes and two negative electrodes. In this case, the positive electrodes and the negative electrodes each have a square shape as viewed in plan. When the light-emitting element includes two or more positive electrodes and two or more negative electrodes, the solder 30 is separated into a number of portions corresponding to the electrodes 12. That is, in the example shown in FIG. 1C, four portions of the solder 30 are provided. When there are a plurality of solder portions 30, damage to the light-emitting element 10 and occurrence of cracks in the solder 30 can be reduced. When the light-emitting element includes a plurality of positive electrodes and a plurality of negative electrodes, the electrodes are preferably arranged so as to be separated at the portion overlapping the edge as viewed in plan.

The electrodes 12 of the light-emitting element 10 can be made of an electrical conductor and specifically can be made of, for example, gold, silver, copper, platinum, iron, nickel, or an alloy thereof. The electrodes 12 can include an ohmic electrode that is in contact with the lower surface of the semiconductor layered structure 11 and a pad electrode connected with the ohmic electrode and connected with an external element. The thickness of the electrodes can be, for example, equal to or greater than 0.5 μm and equal to or smaller than 50 μm, more preferably equal to or greater than 5 μm and equal to or smaller than 20 μm.

### (Light-transmitting Member)

The light-transmitting member 40 is a member capable of transmitting light, which is provided so as to cover the upper surface of the semiconductor layered structure 11 of the light-emitting element 10. Light emitted from the light-emitting element 10 outgoes via the light-transmitting member 40. In the light-emitting device 100 shown in FIG. 1B, or the like, the light outgoes from the upper surface of the light-transmitting member 40. The light-transmitting member 40 can be made of a resin material, an inorganic material, glass, or a combination thereof. The transmittance of the light-transmitting member 40 for the light emitted from the light-emitting element 10 at the peak wavelength is preferably 60% or higher, more preferably 70% or higher, still more preferably 80% or higher.

When the light-transmitting member 40 is made of a resin material, thermosetting resins such as silicone resins, silicone modified resins, epoxy resins and phenolic resins, and thermoplastic resins such as polycarbonate resins, acrylic resins, methylpentene resins and polynorbornene resins can be used. Particularly, silicone resins, which are excellent in light resistance and heat resistance, are preferred. When the light-transmitting member 40 is made of an inorganic material, silicon oxide, aluminum oxide, and the like, can be used. When the light-transmitting member 40 is made of glass, alkali-free glass, soda glass, soda-lime glass, borosilicate glass, aluminosilicate glass, quartz glass, low-alkali borosilicate glass, and the like, can be used.

The light-transmitting member 40 can be made of only such a light-transmitting material or can be made of a mixture containing such a light-transmitting material as the main constituent and a phosphor capable of converting the light from the light-emitting element to light at a different wavelength by excitation, or a light-scattering agent contained therein.

Examples of the phosphor include yttrium-aluminum-garnet-based phosphors, lutetium-aluminum-garnet-based phosphors, terbium-aluminum-garnet-based phosphors, CCA-based phosphors, SAE-based phosphors, chlorosilicate-based phosphors, silicate-based phosphors, oxynitride-based phosphors such as β-sialon-based phosphors or α-sialon-based phosphors, nitride-based phosphors such as LSN-based phosphors, BSESN-based phosphors, SLA-based phosphors, CASN-based phosphors or SCASN-based phosphors, fluoride-based phosphors such as KSF-based phosphors, KSAF-based phosphors or MGF-based phosphors, quantum dots having a perovskite structure, Group II-VI quantum dots, Group III-V quantum dots, and quantum dots having a chalcopyrite structure.

Examples of the light-scattering agent include titanium oxide, silicon oxide, aluminum oxide, zinc oxide, magnesium oxide, zirconium oxide, yttrium oxide, calcium fluoride, magnesium fluoride, niobium pentoxide, barium titanate, tantalum pentoxide, barium sulfate, or particles of glass or the like.

The light-transmitting member 40, which is a member formed into the shape of a plate in advance, can be placed on the light-emitting element 10 using a light-transmitting bonding member 60 as shown in FIG. 1B. In the example shown in FIG. 1B, the bonding member 60 is provided so as to have a small thickness between the light-emitting element 10 and the light-transmitting member 40 and covers the lateral surfaces of the light-emitting element 10. The light-emitting element 10 and the light-transmitting member 40 can be directly bonded together by a direct bonding method without the intervention of the bonding member as shown in FIG. 2. Alternatively, the light-transmitting member 40 can be formed by placing a resin material in a liquid form on the light-emitting element 10 and curing the placed resin material. Alternatively, the light-transmitting member 40 in the form of a thin film can be provided on the light-emitting element 10 as shown in FIG. 3 by film formation method such as sputtering, vapor deposition, atomic deposition, or the like.

The area of the light-transmitting member 40 can be equal to the area of the light-emitting element 10 as shown in FIG. 2. Alternatively, as shown in FIG. 1B, the area of the light-transmitting member 40 can be greater than the area of the light-emitting element 10. It is preferred that the light-transmitting member 40 overlaps the entire surface of the light-emitting element 10 as viewed in plan. For example, the light-transmitting member 40 can overlap the entire surface of the light-emitting element 10 as viewed in plan and can have a greater size than the light-emitting element 10. The light-transmitting member 40 that has a greater size than the light-emitting element 10 can continuously cover the light-emitting element 10 and the cover member 50 as shown in FIG. 1B or FIG. 3. The lateral surfaces of the light-transmitting member 40 can be covered with the cover member 50 as shown in FIG. 1B or FIG. 2, or can be exposed out of the cover member 50 as shown in FIG. 3.

### (Cover Member)

The cover member 50 covers the upper surface 20U of the first electrically-conductive member 21, the upper surface 20U of the second electrically-conductive member 22, and the lateral surfaces of the light-emitting element 10. The cover member 50 can cover the lateral surfaces of the light-emitting element 10 such that the cover member 50 is in contact with the lateral surfaces of the light-emitting element 10. Alternatively, when the bonding member 60 that bonds together the light-transmitting member 40 and the light-emitting element 10 covers part of the lateral surfaces of the light-emitting element 10, the cover member 50 covers the lateral surfaces of the light-emitting element 10 with the bonding member 60 interposed therebetween. The cover member 50 also covers the lower surface of the semiconductor layered structure 11 of the light-emitting element 10. Further, the cover member 50 covers the solder 30 covering the first recessed surface C1 of the first electrically-conductive member 21 and the second electrically-conductive member 22 and at least part of the second recessed surface C2. The cover member 50 can be in contact with the lower surface of the light-transmitting member 40. The cover member 50 can cover the lateral surfaces of the light-transmitting member 40.

The cover member 50 can be capable of reflecting, absorbing, or transmitting light. As the main constituent of the cover member 50, a resin material can be used. Examples of the resin material include thermosetting resins such as silicone resins, silicone modified resins, epoxy resins and phenolic resins, and thermoplastic resins such as polycarbonate resins, acrylic resins, methylpentene resins and polynorbornene resins. Particularly, silicone resins, which are excellent in light resistance and heat resistance, are preferred. When a resin material is used, the cover member 50 can be formed by compression molding or transfer molding after the light-emitting element 10 and the electrically-conductive member 20 are bonded together using the solder 30. In such a case, the cover member 50 can be formed using a pre-melted resin material or can be formed by placing a resin material in a powder form so as to cover the light-emitting element 10 and the electrically-conductive member 20 and thereafter performing compression molding.

The cover member 50 can contain a light-reflecting material such as titanium oxide, zinc oxide, or the like. Alternatively, the cover member 50 can contain a light-absorbing material such as carbon black, titanium black, or the like. The cover member 50 can contain both the light-reflecting material and the light-absorbing material. In such a case, the cover member 50 can contain both the light-reflecting material and the light-absorbing material in a single main constituent. Alternatively, the cover member 50 can include the first cover member that is in contact with the light-emitting element 10 and that is capable of reflecting light and the second cover member that is located outside the first cover member and that is capable of absorbing light.

The cover member 50 can be made of an inorganic material containing, for example, boron nitride or alkali metal silicate. In this case, the cover member 50 can further contain titanium oxide or zirconium oxide.

The cover member 50 can contain both the resin material and the inorganic material.

When the cover member 50 is capable of reflecting light, the reflectance of the cover member 50 for the light emitted from the light-emitting element 10 at the emission peak wavelength is preferably 70% or higher, more preferably 80% or higher, still more preferably 90% or higher.

### (Protective Element)

The light-emitting device 400 can include a protective element. For example, the light-emitting device 400A shown in FIG. 4A, FIG. 4B and FIG. 4C includes a protective element 70 that is provided on both the upper surface of the first electrically-conductive member 21 and the upper surface of the second electrically-conductive member 22 so as to extend from one to the other. The protective element 70 includes an element portion and a pair of positive and negative electrodes provided on the lower surface of the element portion and is connected in parallel with the light-emitting element 10. When the protective element 70 is a protective element having polarity such as Zener diode, the protective element 70 is connected in a reverse direction to the light-emitting element 10. When the protective element 70 is a protective element having no polarity such as varistor, the protective element 70 is connected in a forward or reverse direction to the light-emitting element 10.

The light-emitting devices 400 shown in FIG. 4D, FIG. 4E and FIG. 4F each include two light-emitting elements 10. The light-emitting device 400B shown in FIG. 4D includes two light-emitting elements 10 and two protective elements 70. Two pairs of electrically-conductive members 20 each include a first electrically-conductive member 21 and a second electrically-conductive member 22 and, on the upper surface of each of them, the light-emitting element 10 and the protective element 70 are provided. Such an arrangement enables two light-emitting elements 10 to simultaneously or separately emit light.

The light-emitting device 400C shown in FIG. 4E includes two light-emitting elements 10 and two protective elements 70. The electrically-conductive member 20 includes two first electrically-conductive members 21 and a single second electrically-conductive member 22 interposed between the first electrically-conductive members 21. To each of the two first electrically-conductive members 21, a single light-emitting element 10 and a single protective element 70 are bonded via solder. To the second electrically-conductive member 22, two light-emitting elements 10 and two protective elements 70 are bonded via solder. Such an arrangement enables two light-emitting elements 10 to simultaneously emit light.

The light-emitting device 400D shown in FIG. 4F includes two light-emitting elements 10 and a single protective element 70. The electrically-conductive member 20 includes two first electrically-conductive members 21 and a single second electrically-conductive member 22. The two first electrically-conductive members 21 are shaped so as to have a greater length than the second electrically-conductive member 22. The first electrically-conductive members s 21 include portions between which the second electrically-conductive member 22 is interposed and portions elongated in a transverse direction. The elongated portions of the two first electrically-conductive members 21 are located so as to oppose each other, and the single protective element 70 is located at that portion. That is, the protective element 70 is not bonded to the second electrically-conductive member 22. Two light-emitting elements 10 are bonded to the second electrically-conductive member 22 via solder, and a single light-emitting element 10 is provided to each of the two first electrically-conductive members 21. Since the electrically-conductive member 20 has such a shape, the mechanical strength of the light-emitting device 400D can be improved.

In the example described herein, the light-emitting elements 10 and the protective element 70 are provided on the same plane. When the light-emitting device thus includes a plurality of light-emitting elements 10, the light-emitting device does not need to include the protective element 70. The position where the protective element 70 is placed is not limited to the upper surface 20U of the electrically-conductive member 20 but can be on the lower surface 20D side of the electrically-conductive member 20 or on the lateral surface 20S.

The role of the protective element 70 is to bypass the electric current by reducing the resistance of the parallel circuit formed by the protective element 70 when an excessive voltage load is put on the light-emitting device 400, such that the voltage load between the positive and negative electrodes 12 of the light-emitting elements 10 can be reduced. For example, in the light-emitting device 400 shown in FIG. 4A, or the like, the light-emitting element 10 and the protective element 70 are connected in parallel in a reverse direction, whereby a driving circuit including the light-emitting element 10 and a bypass circuit including the protective element 70 are formed. While the protective element 70 is in operation, the electric current branched to the light-emitting element 10 connected in parallel with the protective element 70 can be reduced as the resistance of the bypass circuit is reduced. For example, in mounting the light-emitting device 400 to a circuit board, the distance between the wirings of the circuit board and the protective element 70 is reduced, i.e., the route of the bypass circuit is shortened, whereby the resistance of the bypass circuit can be reduced. Thus, the load on the light-emitting element 10 can be reduced, and the protection effect on the light-emitting element 10 can be further improved.

In the present embodiment, the protective element 70 and the electrically-conductive member 20 are bonded together using the solder 30 similarly to the bonding of the light-emitting element 10 and the electrically-conductive member 20. Since the solder 30 has a smaller thickness than gold bumps, the distance between the protective element 70 and the wirings of the circuit board can be small when the solder 30 is used as compared with a case where gold bumps are used. Thus, the resistance of the bypass circuit can be reduced as compared with a case where gold bumps are used. Also, it is preferred that the solder 30 for bonding the protective element 70 is provided so as to continuously cover not only the upper surface 20U of the electrically-conductive member 20 but also part of the lateral surface 20S.

The protective element 70 can be provided on the upper surface 200 that is the same as the upper surface 20U of the electrically-conductive member 20 on which the light-emitting element 10 is placed. Alternatively, as shown in FIG. 4B, the protective element 70 can be provided in a recessed portion R formed in the upper surface 200 of the first electrically-conductive member 21 and the second electrically-conductive member 22. When the protective element 70 is thus provided in the recessed portion R, the route of the bypass circuit can be further shortened as compared with a case where the protective element 70 is provided on the upper surface 20U of the electrically-conductive member 20. Accordingly, the resistance of the bypass circuit can be reduced.

The recessed portion R of the first electrically-conductive member 21 and the recessed portion R of the second electrically-conductive member 22 are located between the lateral surfaces 20S of the electrically-conductive member 20 which face each other and the upper surface 20U. The protective element 70 is provided on the bottom surfaces that define the two recessed portions R respectively via the solder 30. The solder 30 for bonding the protective element 70 can be provided so as to extend over the bottom surface that defines the recessed portion R of each of the first electrically-conductive member 21 and the second electrically-conductive member 22 and the lateral surface that is contiguous with the bottom surface. The distance between the first electrically-conductive member 21 and the second electrically-conductive member 22 is greater in the area under the protective element 70 than in the area under the light-emitting element 10. Since the protective element 70 only needs to be electrically connected, the ratio of the size of the electrodes of the protective element 70 to the size of the protective element 70 is small, and the amount of the solder 30 is also small. Therefore, it is preferred that, as shown in FIG. 4B, the solder 30 provided under the protective element 70 continuously covers the upper surface 20U and part of the lateral surface 20S of the electrically-conductive member 20. The light-emitting element 10 and the protective element 70 can be placed in either order.

The cover member 50 is provided inside the recessed portion R so as to cover the protective element 70. Since the protective element 70 is provided inside the recessed portion R, absorption of light from the light-emitting element 10 by the protective element 70 can be reduced. The recessed portion R can have such a size in which the protective element 70 can be provided. The depth of the recessed portion R can be generally equal to the thickness of the protective element 70.

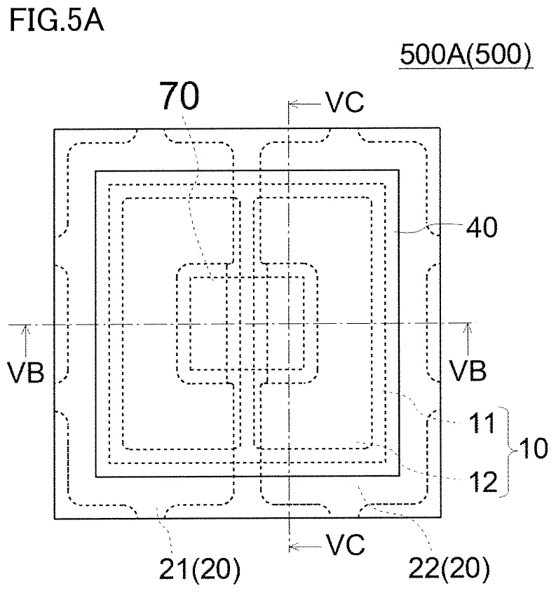

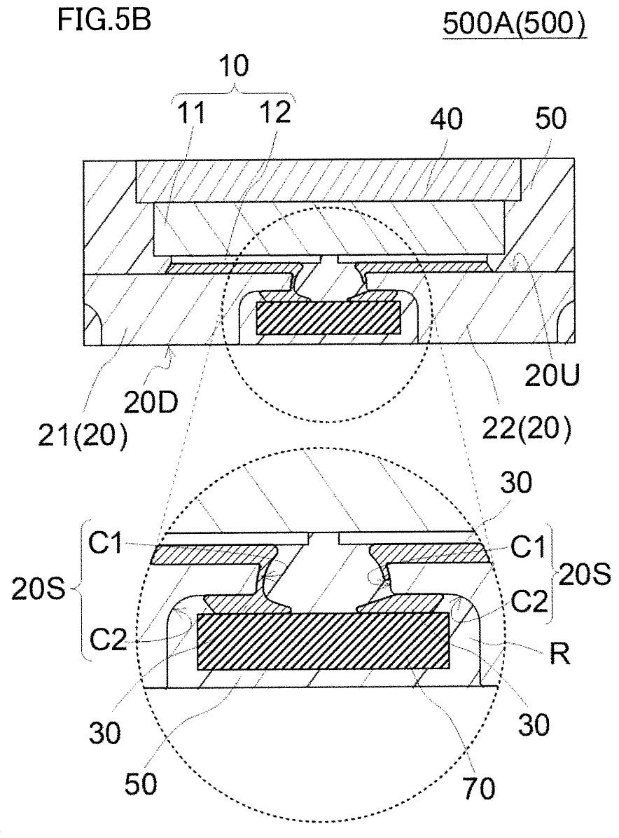

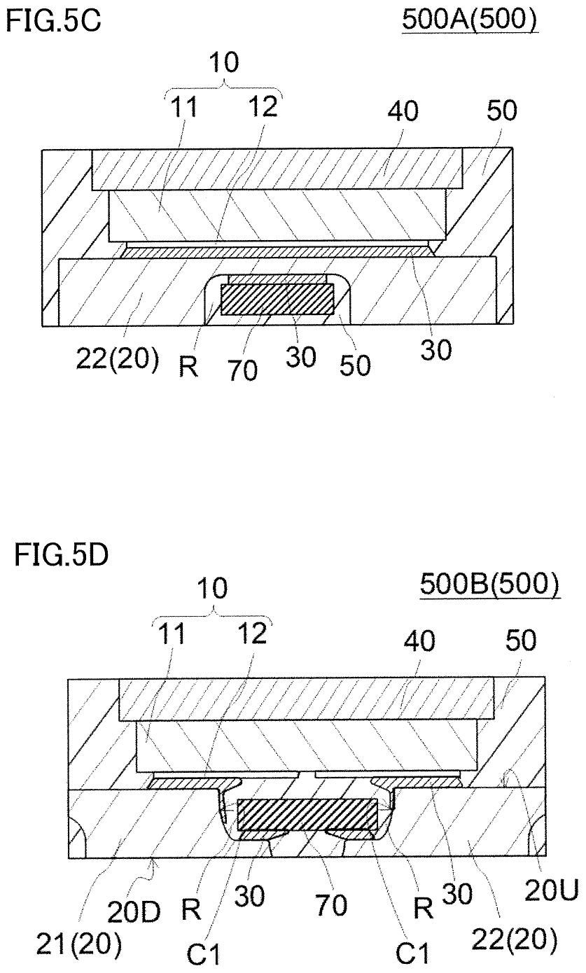

In the light-emitting device 500, the protective element 70 is located so as to overlap the light-emitting element 10. For example, in the light-emitting device 500A shown in FIG. 5A, FIG. 5B and FIG. 5C, the protective element 70 is provided in the recessed portion R formed in the lower surface 20D of the electrically-conductive member 20. The recessed portion R of the first electrically-conductive member 21 and the recessed portion R of the second electrically-conductive member 22 are located at the lateral surfaces 20S of the electrically-conductive member 20 which face each other, and each are contiguous with the lower surface 20D. The protective element 70 is provided on the internal surfaces that define the two recessed portions R respectively via the solder 30. And, the cover member 50 is provided in the recessed portions R. Since the protective element 70 is provided at such a position, absorption of light from the light-emitting element 10 by the protective element 70 can be reduced. When the protective element 70 is provided on the lower surface 20D side of the electrically-conductive member 20, the protective element 70 can be located so as not to overlap the light-emitting element 10 as viewed in plan. In the example shown in FIG. 5A, the protective element 70 is located such that the entirety of the protective element 70 overlaps the light-emitting element 10. In other words, the protective element 70 is located directly below the light-emitting element 10. Due to this arrangement, the increase in size of the light-emitting device 500A as viewed in plan can be reduced. Also, it can be said that the recessed portions R that enable the protective element 70 to be located directly below the light-emitting element 10 are the second recessed surfaces C2 formed in the lateral surfaces 20S of the electrically-conductive member 20. The lateral surface 20S that is contiguous with the upper surface 20U of the electrically-conductive member 20 has the first recessed surface C1, the second recessed surface C2 located at a lower level than the first recessed surface C1, and the third recessed surface located at a lower level than the second recessed surface C2 and contiguous with the lower surface 20D, and this third recessed surface can serve as the recessed portion R.

The protective element 70 is electrically connected with the electrically-conductive member 20 via the solder 30. For example, as shown in FIG. 5B, the solder 30 is provided between the inner surface (second recessed surface C2) of the recessed portion R formed in the lower surface 20D of the electrically-conductive member 20 and the protective element 70. In this case, the solder 30 which connects the second electrically-conductive member 22 shown on the right side in FIG. 5B and the light-emitting element 10 and the solder 30 which connects the protective element 70 and the second electrically-conductive member 22 are separated from each other. That is, the first recessed surface C1 of the second electrically-conductive member 22 is partially exposed out of the solder 30. The solder 30 which connects the first electrically-conductive member 21 shown on the left side in FIG. 5B and the light-emitting element 10 and the solder 30 which connects the protective element 70 and the first electrically-conductive member 21 are connected with each other. That is, the first recessed surface C1 of the first electrically-conductive member 21 is not exposed out of the solder 30 at this position. In the example shown in FIG. 5B, one of the solder 30 connected with the light-emitting element 10 and the solder 30 connected with the protective element 70 is separated, but the other is continuous. Note that, however, the arrangement is not limited to this example. Both of the solders 30 can be separated or continuous.

When, as described above, the light-emitting element 10 is provided on the upper surface 20U side of the electrically-conductive member 20 while the protective element 70 is provided on the lower surface 20D side, the protective element 70 can be placed after the light-emitting element 10 has been placed, or the light-emitting element 10 can be placed after the protective element 70 has been placed.

In the light-emitting device 500B shown in FIG. 5D, the protective element 70 is provided in the recessed portions R formed in the upper surface 20U of the electrically-conductive member 20. The recessed portion R of the first electrically-conductive member 21 and the recessed portion R of the second electrically-conductive member 22 are located at the lateral surfaces 20S of the electrically-conductive member 20 which face each other, and each are contiguous with the upper surface 20U. The protective element 70 is provided on the internal surfaces that define the two recessed portions R via the solder 30. And, the cover member 50 is provided in the recessed portions R. Since the protective element 70 is provided at such a position, the increase in size of the light-emitting device 500B as viewed in plan can be reduced. The internal surfaces that define the recessed portions R include the first recessed surfaces C1 that are contiguous with the upper surface 20U, on which the solder 30 is provided. In the example shown in FIG. 5D, the solder 30 which connects the electrically-conductive member 20 and the light-emitting element 10 and the solder 30 which connects the protective element 70 and the electrically-conductive member 20 are separated from each other. The solder 30 which connects the electrically-conductive member 20 and the light-emitting element 10 and the solder 30 which connects the protective element 70 and the electrically-conductive member 20 can be contiguous with each other.

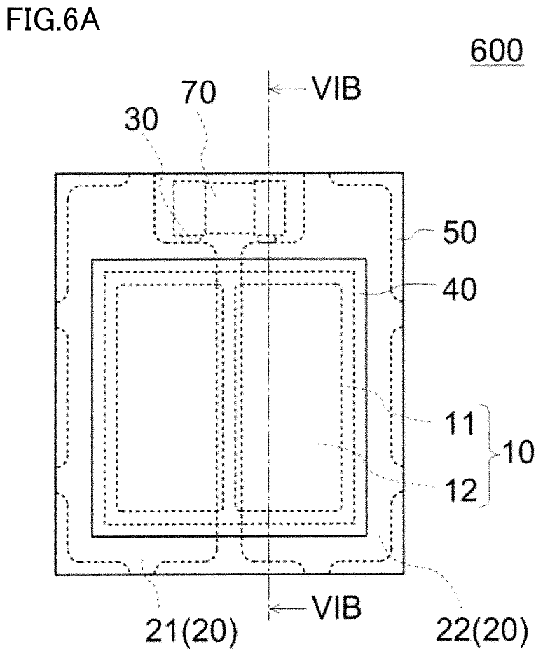

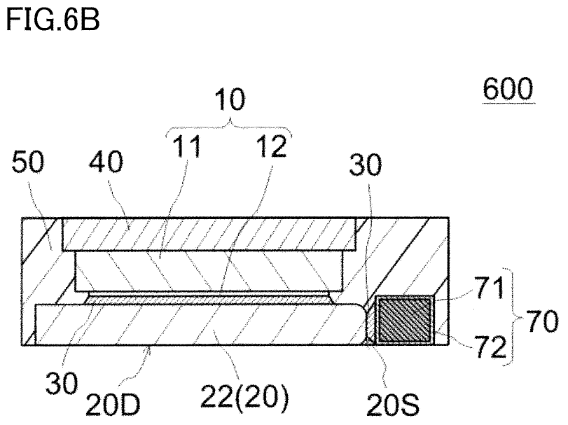

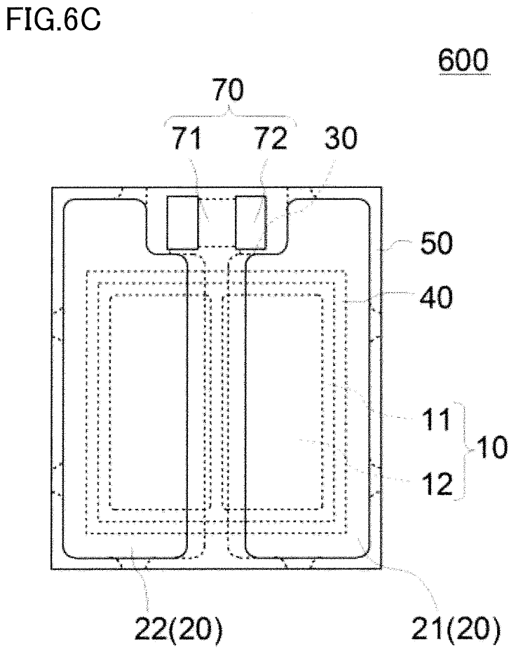

As in the light-emitting device 600 shown in FIG. 6A, FIG. 6B and FIG. 6C, the protective element 70 can be provided on both the lateral surface 20S of the first electrically-conductive member 21 and the lateral surface 20S of the second electrically-conductive member 22 so as to extend from one to the other. The protective element 70 provided at such a position can be entirely covered with the cover member 50 or can be exposed out of the cover member 50 as shown in FIG. 6B.

For example, as shown in FIG. 6C, the protective element 70 includes an element portion 71 having a right-angled parallelepiped shape and electrodes 72 provided at opposite ends of the element portion 71. The electrodes 72 entirely covers the opposite end surfaces and partially covers four lateral surfaces that are contiguous with the end surfaces. In the example shown in FIG. 6A, one lateral surface of the electrodes 72 is connected with the electrically-conductive member 20 via the solder 30. Note that, however, the arrangement is not limited to this example. The solder 30 can be connected with the electrodes 72 that cover the end surfaces of the protective element 70.

As shown in FIG. 6C, one surface of the electrodes 72 of the protective element 70 is exposed out of the cover member 50, while the element portion 71 is covered with the cover member 50. Note that, however, the arrangement is not limited to this example. Both the element portion 71 and the electrodes 72 can be exposed out of the cover member 50. When the electrodes 72 of the protective element 70 are thus exposed out of the cover member 50, the electrodes 72 of the protective element 70 can be electrically connected with the wirings of the circuit board using solder or the like. That is, the voltage can be applied from the circuit board to the protective element 70 without the intervention of the electrically-conductive member 20. Therefore, the route of the bypass circuit can be further shortened.

When the protective element 70 is provided on the lateral surfaces 20S of the electrically-conductive member 20, for example, the electrically-conductive member 20 is placed such that the lower surface 20D of the electrically-conductive member 20 faces the upper surface of an adhesive sheet, or the like, and the protective element 70 is placed so as to correspond to the lateral surfaces 20S of the electrically-conductive member 20. Thereafter, the solder 30 is placed between the lateral surfaces 20S of the electrically-conductive member 20 and the electrodes 72 of the protective element 70 and then cured. Thereby, the protective element 70 can be connected with the lateral surfaces 20S of the electrically-conductive member 20.

Examples of the protective element 70 include Zener diodes and varistors. The protective element 70 includes an element portion and a pair of electrodes provided on the element portion. The element portion of the protective element 70 can have a right-angled parallelepiped shape, and the pair of electrodes can be provided on one surface of the element portion. Alternatively, as shown in FIG. 6A, or the like, the protective element 70 can include an element portion 71 having a right-angled parallelepiped shape and a pair of electrodes 72 provided so as to cover five surfaces in total, including two end surfaces of the element portion 71 which include the short sides and part of four lateral surfaces that are contiguous with the end surfaces. An example of the protective element 70 that includes the electrodes 72 having such a shape is a varistor. When such a protective element 70 is used, the electrodes 72 of the protective element 70 can be exposed out of the cover member 50 at the lower surface of the light-emitting device 600 as shown in FIG. 6C. The size of the protective element 70 is not particularly limited, but can be smaller than, greater than, or equal to the light-emitting element 10.

Embodiments of the present disclosure are, for example, as described below.

### (Appendix 1)

A light-emitting device comprising:

a first electrically-conductive member and a second electrically-conductive member each having an upper surface, a lower surface located opposite to the upper surface, and a lateral surface located between the upper surface and the lower surface;

solder provided on the upper surface of the first electrically-conductive member and the upper surface of the second electrically-conductive member;

a light-emitting element bonded to the upper surface of the first electrically-conductive member and the upper surface of the second electrically-conductive member with the solder;

a light-transmitting member provided on an upper surface of the light-emitting element; and

a cover member covering the upper surface of the first electrically-conductive member, the upper surface of the second electrically-conductive member, and a lateral surface of the light-emitting element,

wherein the lateral surface of the first electrically-conductive member includes a first recessed surface contiguous with the upper surface of the first electrically-conductive member and a second recessed surface located at a lower level than the first recessed surface,

the solder continuously covers the upper surface of the first electrically-conductive member and at least part of the first recessed surface, and

the cover member further covers the solder covering the first recessed surface and at least part of the second recessed surface.

### (Appendix 2)

The light-emitting device of Appendix 1, wherein

the lateral surface of the second electrically-conductive member includes a first recessed surface contiguous with the upper surface of the second electrically-conductive member and a second recessed surface located at a lower level than the first recessed surface of the second electrically-conductive member,

the solder continuously covers the upper surface of the second electrically-conductive member and at least part of the first recessed surface of the second electrically-conductive member, and

the cover member further covers the solder covering the first recessed surface of the second electrically-conductive member and at least part of the second recessed surface.

### (Appendix 3)

The light-emitting device of Appendix 1 or 2, wherein the solder covers a portion of the second recessed surface of the first electrically-conductive member.

### (Appendix 4)

The light-emitting device of any one of Appendixes 1 to 3, wherein the solder covers a portion of the second recessed surface of the second electrically-conductive member.

### (Appendix 5)

The light-emitting device of any one of Appendixes 1 to 4, wherein a thickness of the solder provided on the upper surface of the first electrically-conductive member is greater than a thickness of the solder covering the first recessed surface of the first electrically-conductive member.

### (Appendix 6)

The light-emitting device of any one of Appendixes 1 to 5, further comprising a protective element.

### (Appendix 7)

The light-emitting device of Appendix 6, wherein the first electrically-conductive member and the second electrically-conductive member each have a recessed portion in the upper surface, and the protective element is placed on a bottom surface that defines the recessed portion.

### (Appendix 8)

The light-emitting device of Appendix 6, wherein the protective element is provided on the lateral surfaces of the first electrically-conductive member and the second electrically-conductive member.

While certain embodiments of the present invention have been described with respect to exemplary embodiments thereof, it will be apparent to those skilled in the art that the disclosed invention can be modified in numerous ways and can assume many embodiments other than those specifically described above. Accordingly, it is intended by the appended claims to cover all modifications of the invention that fall within the true spirit and scope of the invention.

What is claimed is:

1. A light-emitting device comprising:
a first electrically-conductive member and a second electrically-conductive member each having an upper surface, a lower surface located opposite to the upper surface, and a lateral surface located between the upper surface and the lower surface;
solder provided on the upper surface of the first electrically-conductive member and the upper surface of the second electrically-conductive member;
a light-emitting element bonded to the upper surface of the first electrically-conductive member and the upper surface of the second electrically-conductive member with the solder;
a light-transmitting member provided on an upper surface of the light-emitting element; and
a cover member covering the upper surface of the first electrically-conductive member, the upper surface of the second electrically-conductive member, and a lateral surface of the light-emitting element,
wherein the lateral surface of the first electrically-conductive member includes a first recessed surface contiguous with the upper surface of the first electrically-conductive member and a second recessed surface located at a lower level than the first recessed surface,
the solder continuously covers the upper surface of the first electrically-conductive member and at least part of the first recessed surface, and
the cover member further covers the solder covering the first recessed surface and at least part of the second recessed surface.

2. The light-emitting device of claim 1, wherein
the lateral surface of the second electrically-conductive member includes a first recessed surface contiguous with the upper surface of the second electrically-conductive member and a second recessed surface located at a lower level than the first recessed surface of the second electrically-conductive member,
the solder continuously covers the upper surface of the second electrically-conductive member and at least part of the first recessed surface of the second electrically-conductive member, and
the cover member further covers the solder covering the first recessed surface of the second electrically-conductive member and at least part of the second recessed surface of the second electrically-conductive member.

3. The light-emitting device of claim 1, wherein the solder covers a portion of the second recessed surface of the first electrically-conductive member.

4. The light-emitting device of claim 2, wherein the solder covers a portion of the second recessed surface of the first electrically-conductive member.

5. The light-emitting device of claim 2, wherein the solder covers a portion of the second recessed surface of the second electrically-conductive member.

6. The light-emitting device of claim 4, wherein the solder covers a portion of the second recessed surface of the second electrically-conductive member.

7. The light-emitting device of claim 1, wherein a thickness of the solder provided on the upper surface of the first electrically-conductive member is greater than a thickness of the solder covering the first recessed surface of the first electrically-conductive member.

8. The light-emitting device of claim 2, wherein a thickness of the solder provided on the upper surface of the first electrically-conductive member is greater than a thickness of the solder covering the first recessed surface of the first electrically-conductive member.

9. The light-emitting device of claim 1, further comprising a protective element.

10. The light-emitting device of claim 2, further comprising a protective element.

11. The light-emitting device of claim 9, wherein the first electrically-conductive member and the second electrically-conductive member each have a recessed portion in the upper surface thereof, and the protective element is placed on bottom surfaces that define the recessed portions of the first electrically-conductive member and the second electrically-conductive member.

12. The light-emitting device of claim 9, wherein the protective element is provided on the lateral surfaces of the first electrically-conductive member and the second electrically-conductive member.

13. The light-emitting device of claim 10, wherein the first electrically-conductive member and the second electrically-conductive member each have a recessed portion in the upper surface thereof, and the protective element is placed on bottom surfaces that define the recessed portions of the first electrically-conductive member and the second electrically-conductive member.

14. The light-emitting device of claim 10, wherein the protective element is provided on the lateral surfaces of the first electrically-conductive member and the second electrically-conductive member.
